(19) United States
(12) Patent Application Publication
(10) Pub. No.: US 2009/0165952 A1
(43) Pub. Date: Jul. 2, 2009

(54) VACUUM PROCESSING APPARATUS

(76) Inventors: Susumu Tauchi, Shunan (JP); Shingo Kimura, Shunan (JP); Minoru Yatomi, Kudamatsu (JP); Masakazu Isozaki, Kudamatsu (JP); Akitaka Makino, Hikari (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/039,994

(22) Filed: Feb. 29, 2008

(30) Foreign Application Priority Data
Dec. 27, 2007 (JP) 2007-335516

(51) Int. Cl. H01L 21/306

(52) U.S. Cl. 156/345.32

(57) ABSTRACT

The invention provides a semiconductor manufacturing apparatus having a high productivity per installed area. In a vacuum processing apparatus provided with a plurality of cassettes on which a cassette is stored, a vacuum feed chamber arranged in a back face side of the atmospheric air feed chamber in a state of being coupled thereto, having a polygonal plane shape and structured such that the wafer is fed in a depressurized inner portion, and a plurality of vacuum processing chambers detachably coupled to a side surface of the vacuum feed chamber, arranged in adjacent thereto and processing the wafer fed to an inner portion from the vacuum feed chamber, a plurality of vacuum processing apparatuses includes a plurality of etching processing chamber carrying out an etching process of the wafer and at least one ashing processing chamber carrying out an ashing process of the wafer, the ashing processing chamber is coupled to a side surface in one of right and left sides as seen from the front face of the vacuum feed chamber, and the atmospheric air feed chamber is arranged so as to be biased to the one side to which the ashing processing chamber is coupled.

### BACKGROUND OF THE INVENTION

(1) Field of the Invention

The present invention relates to a vacuum processing apparatus, and more particularly to a vacuum processing apparatus having a plurality of processing chambers.

(2) Description of Related Art

In the apparatus as mentioned above, particularly in a vacuum processing apparatus processing a substrate-like sample such as a semiconductor wafer or the like to be processed within a depressurized apparatus, there has been demanded an improvement of an efficiency of the process of the substrate corresponding to a processed subject as well as a fine quality and a high precision of the process. Accordingly, in recent years, there has been developed a so-called multiple chamber apparatus provided with a plurality of processing chambers by coupling a plurality of vacuum vessels to one apparatus. In the apparatus provided with a plurality of processing chambers or chambers so as to carry out the process, each of the processing chambers or the chambers is connected to a feed chamber in which an internal gas or its pressure are regulated so as to be depressurized and a robot arm or the like for feeding the substrate is provided.

In the apparatus mentioned above, a processing number of the samples to be processed per unit time by one vacuum processing apparatus is increased, and it is possible to improve a productivity per installed area of a building for a user of a clean room or the like in which a plurality of vacuum processing apparatuses mentioned above are installed. Generally, the apparatuses mentioned above are arranged in an end of a predetermined linear passage to which the vessel storing a sample such as a cassette or the like is fed by the robot or the like in an inner portion of the clean room so as to be lined up along the passage. There can be considered that in accordance that the number of the apparatuses lined up along one passage is increased, the number of the processes per unit time is increased per one facility, and an efficiency is increased.

Accordingly, in the vacuum processing apparatus installed within the building of the facility mentioned above, there has been demanded to reduce an area of a floor of the building occupied by the apparatuses in an installed state. Further, since the apparatuses mentioned above are necessary to be maintained periodically, it is necessary to secure a space for the maintenance. As the space for the maintenance as mentioned above, a space having a predetermined width is normally secured on the floor surface on which the apparatuses are installed, in such a manner that a user or a maintenance worker can pass around the apparatus main body while holding a maintenance supplies material and a tool.

One example of a structure of the multiple chamber mentioned above is disclosed in JP-A-2005-101598 (patent document 1).

Since the prior art mentioned above has been lacking of the following points, problems have been generated.

In other words, since a unit constructing the vacuum processing apparatus, for example, each of portions of the processing unit including an atmospheric air side block feeding a wafer under an atmospheric pressure or a vacuum vessel constructing the wafer corresponding to a processed subject is not efficiently arranged and generates a waste, an installing area or a volume of the processing unit is enlarged, and an occupied area of a whole of the apparatus is enlarged. Accordingly, the number of the vacuum processing apparatuses which can be installed in the installed position is reduced, or the space around the vacuum processing apparatus which the user can use for the maintenance or the movement is reduced.

In the prior art mentioned above, a plurality of processing units provided with the processing chambers in their inner portions are arranged around the vacuum feed chamber in which an inner portion is made vacuum in such a manner as to be coupled to a side surface of the vacuum feed chamber. A plurality of processing units are separated from the vacuum vessel including the vacuum feed chamber in its inner portion, or interrupted from each other so as to be set to a state of being electrically and spatially disconnected from the main body of the vacuum processing apparatus, whereby the maintenance work such as the maintenance, a replacement and the like can be carried out. However, since it is insufficient to consider an efficient layout of the processing unit and the atmospheric air side block for carrying out the works, an efficiency of the work for installing the apparatus and the maintenance work such as the maintenance, the replacement and the like is lowered. Alternatively, since it is necessary to secure a wider space than necessary around the main body of the apparatus in such a manner as to sufficiently carry out the maintenance work as mentioned above, the area for substantially installing the apparatus is increased.

In this case, in the apparatus mentioned above, a magnitude of the vacuum feed chamber is greatly affected by a size of the wafer to be processed and a turning radius of the robot arm installed in the vacuum feed chamber. Further, a magnitude of each of the processing units is greatly affected by a diameter of the wafer, a structure of the vacuum vessel constructing the processing chamber, a power supply and a control apparatus necessary for actuating the unit mounted on the processing unit, and a magnitude and a layout of a utility such as gas and water regulator or the like. Accordingly, the occupied area at a time of installing the whole of the apparatus is affected by the magnitude of the processing chamber or the chamber.

Further, in the prior art mentioned above, the processing units coupled to the processing apparatus are arranged by differentiating the structures and the arranged positions. For example, in the prior art, a plurality of processing units which can execute the processes having the same condition are arranged symmetrically with respect to a vertical surface including a straight line (an axis in a horizontal direction perpendicular to an axis of the passage close to the front face of the apparatus to which the cassette is fed) in a longitudinal direction of a whole of the vacuum processing apparatus. Accordingly, since process characteristics of the processing chambers are different between the processing units, it is necessary to adjust an operating condition of the processing units for reducing the difference of the characteristic between them, or it is necessary to lower a precision of the processing units for setting a common operating condition between the processing units.

As mentioned above, in the prior art, the processing efficiency of the wafer per installed area of the vacuum processing apparatus is deteriorated.

### BRIEF SUMMARY OF THE INVENTION

An object of the present invention is to provide a semiconductor manufacturing apparatus having a high productivity per installed area. Further, the other object of the present invention is to provide a plasma processing apparatus which is easily installed and maintained and has a low manufacturing cost.

The object mentioned above can be achieved by the following vacuum processing apparatus. In other words, in accordance with the present invention, there is provided a vacuum processing apparatus comprising: an atmospheric air feed chamber structured such that a wafer is fed in an inner portion under an atmospheric pressure;

a plurality of cassettes arranged in a front face of the atmospheric air feed chamber and structured such that a cassette in which the wafer is stored is mounted thereon;

a vacuum feed chamber arranged in a back face side of the atmospheric air feed chamber in a state of being coupled thereto, having a polygonal plane shape and structured such that the wafer is fed in a depressurized inner portion; and

a plurality of vacuum processing chambers detachably coupled to a side surface of the vacuum feed chamber, arranged in adjacent thereto and processing the wafer fed to an inner portion from the vacuum feed chamber,

wherein a plurality of vacuum processing apparatuses includes a plurality of etching processing chamber carrying out an etching process of the wafer and at least one ashing processing chamber carrying out an ashing process of the wafer, the ashing processing chamber is coupled to a side surface in one of right and left sides as seen from the front face of the vacuum feed chamber, and the atmospheric air feed chamber is arranged so as to be biased to the one side to which the ashing processing chamber is coupled.

Further, the object can be achieved by a structure in which the vacuum feed chamber is provided with right and left side surfaces to which a plurality of vacuum processing chambers are capable of being coupled and rear side surfaces of the side surfaces, and a plurality of vacuum processing chambers are radially arranged around the vacuum feed chamber. Further, the object can be achieved by a structure in which the ashing processing chamber is arranged in one end of a plurality of radially arranged vacuum processing chambers. Further, the ashing processing chamber is coupled to the one side of the right and left side surfaces, and at least one the etching processing chamber is operational in a state of being coupled to the rear side surface.

Further, the object mentioned above can be achieved by the following vacuum processing apparatus. In other words, in accordance with the present invention, there is provided a vacuum processing apparatus comprising:

an atmospheric air feed chamber structured such that a wafer is fed in an inner portion under an atmospheric pressure;

a plurality of cassettes arranged in a front face of the atmospheric air feed chamber and structured such that a cassette in which the wafer is stored is mounted thereon;

a vacuum feed chamber arranged in a back face side of the atmospheric air feed chamber in a state of being coupled thereto, having a polygonal plane shape and structured such that the wafer is fed in a depressurized inner portion; and

a plurality of vacuum processing chambers detachably coupled to a side surface of the vacuum feed chamber, arranged in adjacent thereto and processing the wafer fed to an inner portion from the vacuum feed chamber,

wherein each of a plurality of etching processing chambers constituting a plurality of vacuum processing apparatuses is provided with a vacuum vessel, a wave guide tube feeding an electric field to an inner portion of the vacuum vessel, an exhaust apparatus exhausting an inner portion thereof, and a sample table on which the wafer is mounted, and arranged positions of the wave guide tube, the exhaust apparatus and the sample table with respect to the side surface are equalized between the etching processing chambers in a state in which the etching processing chamber is coupled to the side surface of the vacuum feed chamber.

Further, the object can be achieved by a structure in which the vacuum processing apparatus is provided with a feed robot arranged within the vacuum feed chamber and feeding the wafer on the basis of a combination of a rotation around an axis in a vertical direction and a motion of an expansion to the inner portion of the vacuum processing chamber or a contraction from the inner portion, and arranged positions of the wave guide tube, the exhaust apparatus and the sample table with respect to the axis in the vertical direction are equalized between the etching processing chambers in a state in which the etching processing chamber is coupled to the side surface of the vacuum feed chamber. Further, the object can be achieved by a structure in which the wave guide tube is arranged by biasing each of the etching processing chambers to any of right and left sides with respect to the axis in the vertical direction.

Further, the object can be achieved by a structure in which the wave guide tube is provided with a tuner arranged in the middle thereof and adjusting an electric wave being propagated in an inner portion of the wave guide tube and an oscillator arranged in an end portion thereof and oscillating the electric wave, and is provided with a portion bent to an upper side between the tuner and the oscillator. Further, the object can be achieved by a structure in which each of the etching processing chambers is provided with a crane coupled to a side wall of the vacuum vessel in the side in which the wave guide tube is biased with respect to the axis in the vertical direction. Further, the object can be achieved by a structure in which the vacuum vessel of each of the etching processing apparatuses is provided with an approximately rectangular parallelepiped shape, and a maintenance space for a user is provided between the adjacent etching processing apparatuses.

Other objects, features and advantages of the invention will become apparent from the following description of the embodiments of the invention taken in conjunction with the accompanying drawings.

### BRIEF DESCRIPTION OF THE SEVERAL VIEWS OF THE DRAWING

FIG. 1A is a perspective view as seen from a front side and shows a whole structure of a vacuum processing apparatus in accordance with an embodiment of the present invention;

FIG. 1B is a perspective view as seen from a rear side and shows the whole structure of the vacuum processing apparatus shown in FIG. 1A;

FIG. 2A is a top elevational view showing an outline of a structure of the vacuum processing apparatus in accordance with the embodiment shown in FIG. 1;

FIG. 2B is a side elevational view showing the outline of the structure of the vacuum processing apparatus in accordance with the embodiment shown in FIG. 1;

FIG. 3 is a view showing an outline of a structure of a processing unit shown in FIG. 1;

FIG. 4 is a vertical cross sectional view showing an outline of a structure of a processing chamber portion in the processing unit shown in FIG. 1;

FIG. 5 is a top elevational view showing a structure in which the side processing unit is removed in the embodiment shown in FIG. 1; and

FIG. 6 is a top elevational view showing an outline of a structure of a modified embodiment of the embodiment shown in FIG. 1.

### DETAILED DESCRIPTION OF THE INVENTION

A description will be given below of an embodiment in accordance with the present invention with reference to the accompanying drawings.

### Embodiment 1

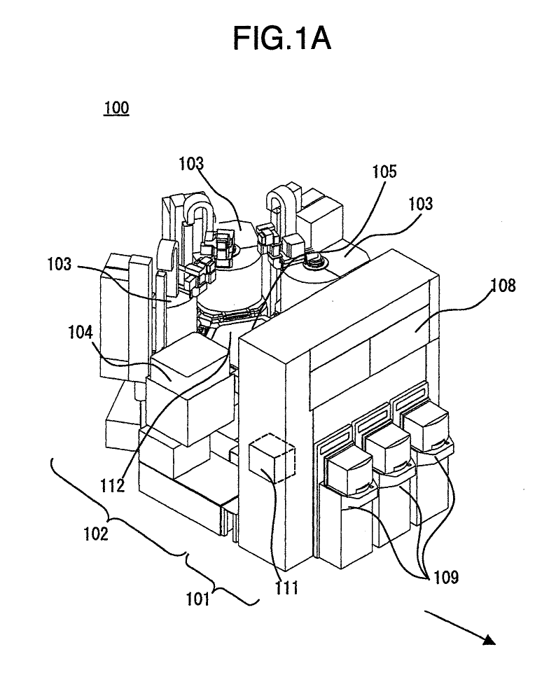

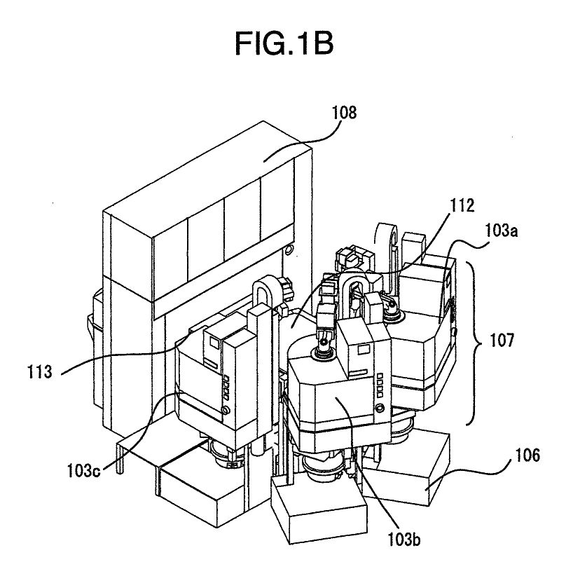

A description will be given of an embodiment in accordance with the present invention with reference to FIGS. 1 to 4. FIGS. 1A and 1B are perspective views showing a whole structure of a vacuum processing apparatus in accordance with the embodiment of the present invention. FIG. 1A is a view as seen from a front side, and FIG. 1B is a perspective view as seen from a rear side.

In this drawing, a vacuum processing apparatus 100 in accordance with the present embodiment is roughly divided into two front and rear blocks. A front side of the vacuum processing apparatus 100 corresponds to an atmospheric air side block 101 structured such that a wafer fed to the apparatus is fed to a chamber depressurized under an atmospheric pressure so as to be fed to a processing chamber. A rear side of the vacuum processing apparatus 100 corresponds to a vacuum side block 102. The vacuum side block 102 is provided with processing units 103 and 104 having processing chambers depressurizing and processing the wafer, a feed unit 105 feeding the wafer to the processing chambers under the depressurized pressure and a plurality of lock chambers connecting the feed chamber 105 and the atmospheric air side block 101, and these elements correspond to units which are depressurized in their inner portions and can be maintained at a high degree of vacuum, and are provided with devices such as vacuum pumps or the like which can achieve the degree of vacuum.

The atmospheric air side block 101 has a casing 108 corresponding to a box-shaped vessel provided with a feed robot (not shown) in an internal space, and is provides with three sets of wafer cassette tables 109 attached to the casing 108 and storing the wafer for processing or cleaning therein. Further, the feed robot carries out a work for carrying in or out the wafer between a cassette on the cassette tables 109 and lock chambers 113 and 113′ coupled to a side surface of a back surface of the casing 108. Further, the atmospheric air side block 101 is provided with a positioning portion 111 on the casing 108, and positions the wafer fed within the positioning portion 111 in correspondence to a posture of a wafer layout within the cassette table 109 or the lock chamber 113 or 113′.

In the casing 108 arranged in the atmospheric air side block 101, a side face in a front face side indicated by an arrow in the drawing faces to a passage in which the cassette storing the wafer therein is fed. A plurality of (three in the present embodiment) cassette tables 109 arranged in parallel in a lateral direction are provided on a side surface of a front face which is in parallel to the feed passage in such a manner that an upper face on which the cassette is mounted has the same height. If the cassette storing the wafer therein is mounted on the cassette table 109, the wafer is fed within a space in an inner portion of the casing 108 under the atmospheric pressure between the inner portion of the cassette and the lock chamber 113 or 113′ of the feed unit 105. In other words, the casing 108 corresponds to an atmospheric air feed vessel, the robot is moved and driven on parallel axes of the side surface in the front face side in the inner portion of the internal atmospheric air feed chamber, and the wafer is transferred between the cassette and the lock chambers 113 and 113′.

Further, the processing units 103a to 103c and 104 of the vacuum side block 102 in the present embodiment correspond to etching processing units provided with etching vessels carrying out an etching process of the wafer fed from the cassette table 109 to the vacuum side block 102, the processing unit 104 corresponds to an ashing processing unit carrying out an ashing process of the wafer, and the feed unit 105 is provided with a feed chamber 112 to which the processing units are detachably mounted, and in which an inner portion is depressurized in a high degree of vacuum so as to be maintained. Further, in a lower portion of the vacuum side block 102, there is arranged a bed 106 storing utilities such as reservoir portions of necessary gas and refrigerant, exhaust portions thereof, power supplies supplying an electric power thereto and the like in correspondence to the processing units mentioned above and having a rectangular flat surface.

In this case, the processing unit 104 is a unit in which the wafer applied the processes by the processing units 103a to 103c is applied the thereafter process, and there is carried out an ashing process of a resist mask for a specific shape of the wafer surface and a removing process of a gas component having a high corrosive used for the etching process, after the etching process of shapes of a groove and a hole of the specific shapes of the wafer surface. In the apparatus mentioned above, after the wafer is taken out from the cassette mounted on the cassette table 109 and is fed to the inner portion of the lock chamber 113 or 113′ set to the atmospheric pressure by the robot in the atmospheric air feed chamber within the casing 108, the sealed lock chamber 113 (113′) is depressurized so as to be set to substantially the same pressure as the feed chamber 112. Thereafter, the wafer is taken out by the robot within the lock chamber 112 so as to be fed to any one of the predetermined etching processing units 103a to 103c and be applied the etching process in the inner portion thereof. Then, the wafer is again fed into the processing unit 104 within the depressurized feed chamber 112 and an after treatment is applied to the wafer. Thereafter, the wafer is carried out to the atmospheric air side block 101 from the feed chamber 112 via the lock chamber 113 (or 113′) by the robot so as to be turned back to the original position of the original cassette.

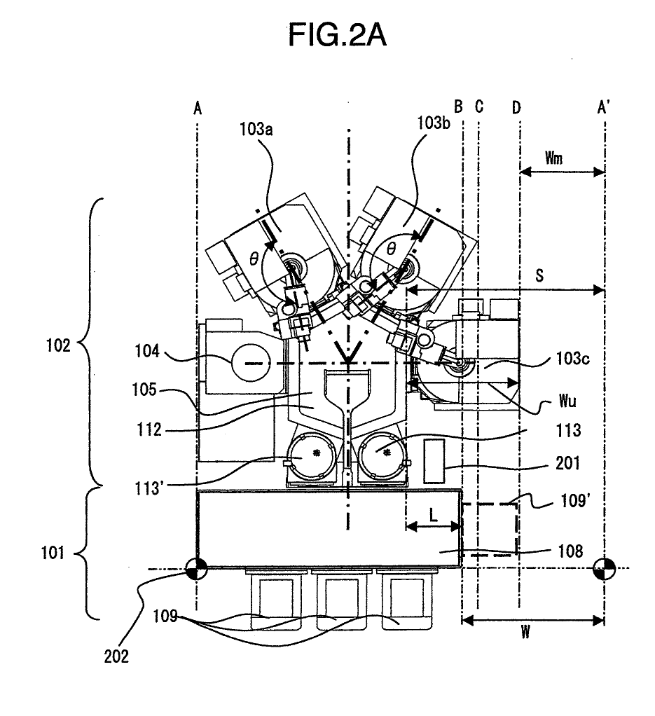

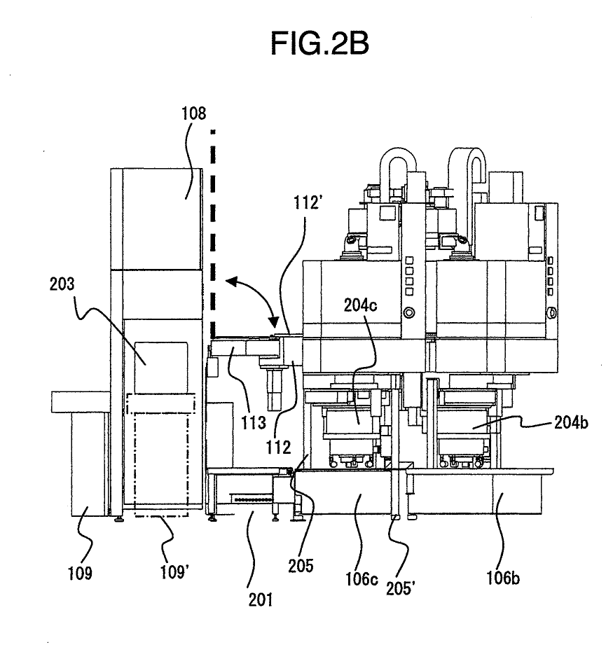

FIGS. 2A and 2B are plan views showing an outline of a structure of the vacuum processing apparatus 100 in accordance with the embodiment shown in FIG. 1, in which FIG. 2A is a view as seen from an upper side, and FIG. 2B is a view as seen from a side portion. In the present embodiment, the atmospheric air side block 101 arranged in the front side of the vacuum processing apparatus 100 corresponds to a portion carrying out a handling such as a feed, a storage, a positioning and the like of the wafer under the atmospheric pressure, and the vacuum side block 102 in the rear side corresponds to a processing block processing the wafer as well as carrying out the feed, the process and the like of the wafer under the pressure depressurized from the atmospheric pressure and increasing or decreasing the pressure in a state of mounting the wafer.

As mentioned below, in the present embodiment, the casing 108 arranged in the atmospheric air side block 101 in the front face side of the vacuum processing apparatus 100 is arranged so as to be biased to a left side with respect to a horizontal direction as seen from the same front side of the vacuum processing apparatus 100 as the processing unit 104.

Further, as mentioned above, between the feed chamber 112 constructing the feed unit 105 and the atmospheric air side block 101, there are arranged the lock chambers 113 and 113′ connecting them and exchanging the wafer therebetween. The lock chamber 113 or 113′ is boosted to the atmospheric air in the inner side after the wafer mounted to the robot arm (not shown) arranged in the inner portion of the feed chamber 112 within the vacuum feed vessel having the decompressed inner side so as to be fed is installed, and the wafer is mounted to the other robot arm (not shown) arranged within the atmospheric air side block 101 so as to be taken out to the atmospheric air side block 101. The taken-out wafer is returned to the original position within the cassette table 109 or returned to any one of the cassettes. Alternatively, after the wafer taken out from any one of the cassette tables 109 by the robot arm is installed within the lock chamber 113 or 113′ set to the outside air pressure, the wafer is mounted to the robot arm within the feed chamber 112 in which the inner portion is depressurized so as to pass through the inner side of the feed chamber 112 and is fed to any one of the processing units 103a to 103c or the processing unit 104.

In order to carry out the actuation mentioned above, to the lock chamber 113 or 113′, there is connected a gas exhaust apparatus and a gas feed apparatus connecting between the atmospheric air side block 101 and the feed chamber of the feed unit, increasing or decreasing the pressure in the inner portion in a state in which the wafer fed to the inner side is mounted, and maintaining the pressure. Accordingly, a gate valve (not shown) opening or closing front and rear sides so as to seal the inner portion is arranged in the lock chamber 113 or 113′. Further, a table on which the wafer is mounted is arranged in an inner side thereof, and there is provided a means for fixing the wafer such that the wafer is not moved at a time when the pressure in the inner portion is increased or decreased. In other words, the lock chambers 113 or 113′ is structured such as to be provided with a seal means resisting a difference between internal and external formed pressures in a state of mounting the wafer in an inner side.

The feed unit 105 is constituted by a feed chamber 112 in which an inner side is depressurized and the robot arm (not shown) feeding the wafer between each of the processing units 103a to 103c and 104 and the lock chamber 113 is arranged in the inner portion, and a plurality of lock chambers 113 and 113′. In this case, in the present embodiment, the robot arm (not shown) feeding the wafer is arranged in the inner portion of the feed chamber 112, and the sample is exchanged between four processing units arranged around the feed chamber 112 and the atmospheric air side block 101.

Further, as mentioned above, in the present embodiment, the processing units 103a to 103c and 104 are constituted by three etching processing units and one ashing processing unit, and these units are provided such that each of the vacuum vessels is detachably coupled to each of side surfaces of the feed chamber 112 of the feed unit 105. The vacuum vessel constructing the feed chamber 112 is provided with a pentagonal or hexagonal flat surface shape, and side surfaces constructing lines in right and left ends as seen from the front face side of the vacuum processing apparatus 100 in a lower side of the drawing form vertical surfaces to parallel symmetrical floors which has an equal distance to an axis in a longitudinal direction of the vacuum processing apparatus 100 passing through a center within the feed chamber 112 in a vertical direction of the drawing. Further, two side surfaces corresponding to lines in a rear side of an upper side of the drawing form vertical surfaces arranged symmetrically while having a predetermined angle with respect to the axis in the longitudinal direction.

The feed chamber 112 is structured such that three etching processing units 103a to 103c are detachably connected to the symmetrical side surfaces corresponding to two lines in a far side of the feed chamber 112 and the side surface corresponding to the line in the right end as seen from the upper surface, and one ashing processing unit 104 is connected to the side surface in the left end, and the lock chambers 113 and 113′ are connected to the remaining line of the feed chamber 112. In other words, in accordance with the present embodiment, three etching processing chambers and one ashing processing chamber are arranged radially around the feed chamber 112 having the polygonal flat surface shape.

Further, in the present embodiment, the processing units 103 and 104 connected to the feed units 105 are structured detachably with respect to the feed unit 105, and the lock chambers 113 and 113′ and the feed chamber 112 are detachably structured and connected, in the feed unit 105. Further, each of the processing units 103a to 103c forms a unit having the same shape with respect to a center of the feed chamber 112 or having the same layout of the devices installed thereto, in a state of being installed to the main body of the vacuum processing apparatus 100. Each of the processing units 103a to 103c has a vacuum vessel and a sample table on which the wafer arranged in the processing chamber in the inner portion thereof is mounted, and is arranged in such a manner that a center has an equal distance in a vertical (perpendicular to the floor surface) direction passing through the center of rotation of the robot rotating and feeding within the feed chamber 112. The ashing processing unit 104 is arranged in such a manner as to be provided with the vacuum vessel, the processing chamber and the sample table in the same manner.

In the present embodiment, the vacuum side block 102 structured such as to include the processing units 103a to 103c and 104, and the feed unit 105 is roughly divided into upper and lower portions. Each of them is divided into a chamber portion in which the inner side is depressurized and the wafer made of a semiconductor material corresponding to the sample to be processed is handled, and a bed portion arranged in a lower side of the chamber portion so as to support the chamber portion, including the bed 106 in which devices necessary for the chamber portion are arranged in an inner side and arranged on a floor within a chamber in which the vacuum processing apparatus 100 is installed.

The bed 106 in the bed portion of each of the processing units 103a to 103c and 104 has an approximately box-shaped rectangular parallelepiped shape, and stores utilities and controllers necessary for the chamber portion in an upper side thereof in its inner portion. The bed frame including the bed 106 in its inner portion is formed as a frame body in which the bed 106 is stored, and is formed as a box body having a beam having a strength supporting the chamber portion arranged in an upper side thereof, and a plate covering the bed 106 is arranged in an outer side thereof. The utilities can be listed up, for example, a power supply for feeding an electric power to each of the sensors or the like, and a gas storage portion for feeding to the sample table on which the wafer corresponding to the sample is mounted and fixed within a signal interface processing chamber for giving and receiving a signal input to and output from each of the processing units and adjusting the signal.

Further, the lock chamber 113 is arranged between the atmospheric air side block 101 and the feed chamber 112 of the vacuum side block 102 in the rear side of the atmospheric air side block 101, however, a gap is formed with respect to the bed 106. A back surface side of the atmospheric air side block 101 is formed as a feed path of a gas, a refrigerant, a power supply or the like fed to the vacuum side block 102.

In other words, a place in which the vacuum processing apparatus 100 is installed is typically set to a room inside such as a clean room in which the air is purified, however, in the case that a plurality of apparatuses are installed, it is general that the various gases, refrigerants and power supplies fed to the vacuum processing apparatus 100 are put together and arranged in the other positions, for example, the other storey such as the lower floor below the floor on which the apparatus main body is installed, and pipe lines are attached to each of the apparatus main bodies. In the present embodiment, a connecting interface 201 to the vacuum processing apparatus 100 main body side on the feed line of the utilities such as the pipe line of the gas and the refrigerant from the other position, or electric wires from the power supply is arranged on the floor in a space between the back surface of the atmospheric air side block and the processing unit 103c.

The connecting interface 201 serves as a distributor in which the feed line of the utilities from the other position is connected to one side, and the line of the utilities distributed to each of the processing units 103a to 103c and 104 and the feed chamber 112 so as to extend is connected to the other side. The connecting interface 201 serving as the distributor is provided with a controller controlling the feed as well as a display apparatus displaying an amount and a speed of the feed in each of the utilities. Accordingly, the user can easily maintain, inspect and adjust the utilities collectively in a loose fitting space in which the back face side work of the atmospheric air side block 101 is easily carried out.

The vacuum processing apparatus 100 in accordance with the present embodiment is installed on the floor surface of the building of the user by setting a position projected onto the floor surface in which the vacuum processing apparatus 100 is installed, in a left end lower side of the front face side of a lower side of the drawing of the casing 108 to a reference position 202. Further, a line A corresponding to a line intersecting a floor surface of a surface perpendicular to a floor surface in a longitudinal direction passing through the reference position 202 coincides with a left end as seen from the front side of the processing unit 104. The left end of the processing unit 104 corresponds to a left end of the vacuum processing apparatus 100 itself, a position of the left end is positioned on the line A in the longitudinal direction passing through the reference position 202 for the installation of the vacuum processing apparatus 100 main body, and the line A is a line indicating a left end of a region on the floor surface in which the vacuum processing apparatus 100 is installed.

As mentioned above, in the present embodiment, the left end surface of the casing 108 coincides with the left end of the processing unit 104 corresponding to the left end of the vacuum processing apparatus 100 main body, however, if a distance in a lateral direction (a horizontal direction) between the reference position 202 and the left end of the processing unit 104 (the left end of the vacuum processing apparatus 100) is known, the left end (the reference position 202) of the casing 108 may be arranged in a right side of the left end of the processing unit 104 (the left end of the vacuum processing apparatus 100). The layout mentioned above reduces an area occupied by the floor surface in a state in which the vacuum processing apparatus 100 is installed.

Further, in the present embodiment, three cassette tables 109 are arranged in the side surface in the front face side arranged in parallel to the feed direction so as to face to the fed passage of the cassette of the casing 108. On each of the cassettes 109, there is normally mounted the cassette in which at least one lot having a plurality of product wafers processed for manufacturing a product such as a semiconductor device or the like.

Further, on the other hand, the positioning portion 111 is arranged in an inner side of the end portion in a left side of the drawing of the casing 108, an auxiliary port 203 is arranged on a right side surface of the drawing of the casing 108, and the other cassette table 109′ can be arranged in this side surface. The auxiliary port 203 is provided with a dimension and a layout which are in common with a plurality of apparatuses, in such a manner that it is possible to install an apparatus optically inspecting a retracting cassette or wafer in which the wafer before or after the process in the vacuum side block 102 is temporarily stored, in addition to a load port which is opened and closed in correspondence to the installation of the cassette in the case that the cassette table 109′ is installed and communicates or interrupts between the cassette and the room inside for feeding the atmospheric air within the casing 108.

A line B corresponding to a line which is in parallel to the longitudinal axis of the vacuum processing apparatus 100 passing through the vertical side surface corresponding to the right end of the casing 108 and obtained by projecting the vertical surface on the floor passes through the floor surface in which the processing unit 103c coupled to the right end side surface of the feed chamber 112 covers an upper side, and passes through the floor surface occupied by the processing unit 103b in the rear side thereof. In other words, the position of the line B laps over the region on the floor surface in which the processing units 103b and 103c are installed. Further, the vertical surface which passes through the right end of the processing unit 103c in the coupled state and is in parallel to the longitudinal axis coincides with the right end of the auxiliary cassette table 109′ arranged on the right side surface of he casing 108 or is positioned further in a right side. A line D corresponding to a line in which the surface intersects the floor surface indicates a right end of the installed region on the floor surface of the vacuum processing apparatus 100.

The vacuum processing apparatus 100 in accordance with the present embodiment is installed in adjacent to the other processing apparatus in parallel to the feed path of the passage in which the forward cassette of the casing 108 is fed. The adjacent processing apparatus is arranged in parallel to the forward side feed path in the same manner, and is generally installed in such a manner that the position of the front surface of the box body of the casing 108 coincides with the line which is parallel to the feed path.

A line A′ corresponding to a left end exists in the apparatus which is adjacent at this time, and a space in which the user can pass for maintaining or inspecting any of two adjacent apparatuses is installed on the floor between the line A7 and the line D in FIG. 2A. This space forms a working space, for example, in the case that the user passes while mounting the maintenance supplies to a conveyor such as a wheeled wagon or the like or the worker actually works about each of the processing units 103b and 103c.

In the present embodiment, in the processing units 103a to 103c and 104, at least one unit is detachably coupled to the feed chamber 112 while the other unit is coupled to the feed chamber 112 so as to be under operation. There is a case that the processing units 103b and 103c mentioned above are detached from the main body so as to be replaced, after being installed to the floor surface together with the vacuum processing apparatus 100 main body, or are coupled or installed newly to the main body after the main body is installed to the floor surface in a state in which the main body does not couple any of the processing units. In the case mentioned above, if the atmospheric air side block 101 is moved or the vacuum processing apparatus 100 main body is moved, it takes a lot of time to carry out the work for installing the unit, and an efficiency of the apparatus is lowered.

Accordingly, it is necessary to install the vacuum processing apparatus 100 in such a manner that any one of he processing units 103a to 103c can pass. On the other hand, in order to improve the efficiency of manufacturing the semiconductor device manufactured by the user, it is demanded to suppress a waste in the region substantially occupied by the vacuum processing apparatus 100 on the installed floor surface so as to reduce the area.

In the present embodiment, the position of atmospheric air side block 101 or the casing 108 is arranged while taking the problem mentioned above into consideration. The line B indicating the right end of the casing 108, which is the right end of the atmospheric air side block 101 detached the auxialy cassette table 109′ at the auxialy port 203 is positioned in a left side of the processing unit 103c portion corresponding to the right end of the apparatus main body, the line D corresponding to the position of the leading end in a depth direction in which the processing unit 103c passes through the coupled surface coupled to the feed chamber 112 and passes through the center of rotation of the robot in the feed chamber 112 in the present embodiment, that is, the processing unit 103c is positioned so as to protrude to a right side as seen from the front side of the apparatus main body in comparison with the right end of the casing 108 or the right end of the atmospheric air side block 101. Further, the line B is positioned in a left side of the corner portion of the processing unit 103b, that is, the processing unit 103b protrudes to the right side in comparison with the right end of the casing 108. In accordance with the structure mentioned above, it is possible to suppress the waste of the region substantially occupied by the apparatus on the floor surface in which the vacuum processing apparatus 100 is installed.

As mentioned above, the apparatuses are generally installed side by side along the passage for feeding the cassette, however, in accordance that the interval of the apparatuses is smaller, the number of the apparatuses which can be installed within the building such as one clean room or the like is increased, so that a manufacturing efficiency of the user is improved and a manufacturing cost is lowered. The region demanded at a time when the apparatuses are installed can be considered by a width in a lateral direction along the feed path and the depth direction perpendicular to the path.

In the case that the right end of the casing 108 or the device such as the auxiliary cassette table 109′ installed to the right surface of the casing 108 is positioned in the right of the right end of the processing unit 103c, the right end of the apparatus comes to the right end of the casing 108 (or the auxiliary equipment), and the line D is positioned in the right end of the casing 108.

In this case, the line D is positioned at a position which is a certain distance away from the processing unit 103c in the right side of the drawing, the space for the maintenance is necessary in further the right side of the line D, and a width of the substantial region in which the apparatus is installed becomes larger at a width Wm of the space. On the other hand, the space in the outer peripheral side of the processing unit 103c forms a working space for applying the work thereto, however, the space between the line D and the right end of the processing unit 103c exists further in the apparatus side of the space for the maintenance, and a waste is generated in the region necessary for installing.

In accordance with the present embodiment shown in FIG. 2A, the waste space mentioned above runs short, and the width of the substantial region demanded for installing is constituted by a width in a lateral direction of the vacuum processing apparatus 100 main body and the width Wm of the working space, whereby the waste space is reduced. Further, a process to be necessary is different in accordance with the user, and the number of the units is different. However, in the case that the number of the units is only three or only two, the width of the apparatus comes to a distance between the corresponding portion constructing the processing units 103c and 103c positioned in the right end and the left end of the apparatus, and the width of the apparatus is lowered in correspondence to the reduction of the number of the processing units.

Further, the right end of the casing 108 is arranged at a position at which the processing units 103b and 103c pass between the casing 108 and the adjacently arranged apparatus by utilizing the working space having the width Wm in some cases so as to be movable to the front surface side. In other words, the distance W between the line B indicating the right end of the casing 108 and the line A′ indicating the left end of the rightward adjacent apparatus on the drawing is structured such as to be larger than the minimum width of the processing unit 103c, that is, a magnitude Wu in the depth direction in the present embodiment. Further, the position of the line B indicating the right end of the casing 108 is made larger than a half position of a distance S between the line A′ corresponding to the left end position of the adjacent apparatuses and a position of a right end of a side surface or a coupled portion in a state in which the processing unit 103c is coupled to the feed chamber 112, and a length L at which the right end portion of the casing 108 protrudes to the right from the side surface of the feed chamber 112 or the right end of the coupled portion is set to be equal to or less than one half of the distance S.

In this case, a magnitude Wu′ in the depth direction of the processing unit 104 carrying out an after treatment is made smaller than the magnitude Wu in the depth direction of the processing unit 103c carrying out the etching process.

Further, as shown in FIG. 2B, an upper portion of the vacuum vessel constituting the feed chamber 112 is provided with a lid 112′ which is rotated around a hinge arranged near the back surface of the casing 108 so as to be capable of opening and closing the vacuum vessel. This rotation is achieved by a crane (not shown) around the hinge positioned between the lock chambers 113 and 113′ above the lock chambers 113 and 113′ near the coupled portion between the lock chambers 113 and 113′ and the back surface of the casing 108. A seal brought into contact with the main body of the feed chamber 112 so as to seal the feed chamber 112 in an airtight manner is arranged in a surface in an inner side (in a lower side of the drawing) of the lid 112′ so as to be aligned with a shape of the polygonal lid 112′.

Further, each of the processing units 103b and 103c supports a chamber portion to which a plurality of columnar support members 205 and 205′ arranged on the plane above the beds 106b and 106c are coupled so as to be mounted thereon, and an exhaust apparatus including a vacuum pump such as a turbo molecular pump or the like for exhausting the internal processing chamber so as to depressurize is arranged in a space between the chamber portion and the beds 106b and 106c so as to be connected to a bottom surface of the vacuum vessel.

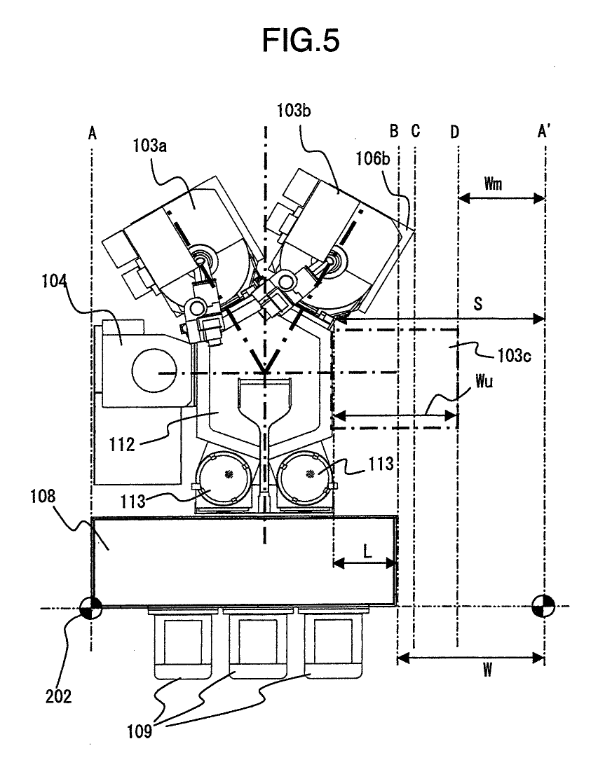

A description will be given of the structure of the present embodiment shown in FIG. 2 and a structure in the case that the processing unit 103c is omitted therefrom in a comparing manner. FIG. 5 is a top elevational view showing the structure in which the processing unit 103c is removed from the embodiment shown in FIG. 1.

In this drawing, the structure in which the processing unit 103c shown in FIG. 2A is not provided is a difference from the structure shown in FIG. 2A, and the same reference numerals are attached to the other common structures and a description thereof will be omitted. In the present embodiment, since the processing unit 103c is not provided, an actual right end portion of eh vacuum processing apparatus 100 comes to a right end portion in the rear side in the depth direction of the bed 106b of the processing unit 103b positioned at the far end, and the line C corresponding to the line by which the surface passing through the right end and being perpendicular to the parallel floor to the axis in the longitudinal direction of the apparatus main body intersects the floor surface indicates the right end position in the lateral direction of the apparatus. On the other hand, the line C is arranged in the right side as seen from the front side of the apparatus in comparison with the line B corresponding to the position of the side surface in the right end of the casing 108.

In this case, any one of the processing units 103a and 103b carrying out the etching process corresponds to a unit mainly carrying out the process, and the other may be used as an auxiliary unit in the case that the one is stopped being actuated due to the maintenance, a trouble or the like. Further, since the processing unit 103c is not provided, the position of the right end portion of the vacuum processing apparatus 100 comes to the line C from the line D. Accordingly, it is possible to reduce the waste space between the working space between the vacuum processing apparatus 100 and the adjacent apparatus in the right side of the right end of the vacuum processing apparatus 100 and the right end of the processing unit 103b.

Further, the interval between the line B and the line A′ shown in this drawing is set larger than the minimum width Wu of the processing unit 103c, and it is possible to transfer the processing unit 103c from the front side of the vacuum processing apparatus 100 to the vacuum side block 102 in the rear side of the casing 108 within the space between the casing 108 and the apparatus adjacent thereto in the right side of the drawing, at a time of replacing the processing unit 103c or newly coupling and attaching the processing unit 103c to the side surface of the feed chamber 112. Accordingly, it is possible to inhibit the casing 108 or the apparatus main body from being moved for moving the unit so as to increase an amount of work and lower an efficiency.

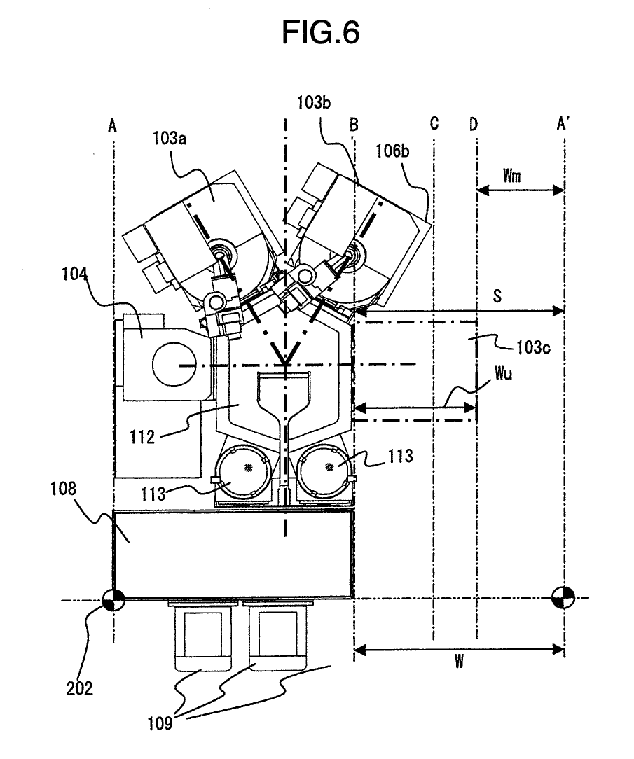

Next, a description will be given of a modified embodiment having a different structure from the embodiments shown in FIGS. 1 to 2 and FIG. 5 with reference to FIG. 6. In this drawing, a difference from the structure shown in FIG. 2A or FIG. 5 exists in a structure in which the processing unit 103c shown in FIG. 2A is not provided and the position of the right end of the casing 108 is different, and a number of the cassette tables 109 in the front face side of the casing 108, and the same reference numerals are attached to the other common structures and a description thereof will be omitted.

In this drawing, the side surface of the right end of the casing 108 is structured such as to coincide with the right end in the drawing of the lock chamber 113 or come such close to the right end as to be assumed to be substantially the same position. Further, this position is structured such as to coincide with the right end of the coupled portion to the processing unit of the right wall surface which is parallel to the axis in the longitudinal direction of the apparatus in the feed chamber 112 or come such close to the right end as to be assumed to be substantially the same position.

Further, only two cassette tables 109 are arranged in the front face side of the casing 108. Further, since the auxiliary port 203 is arranged on the side surface in the right end of the casing 108 in the same manner as the embodiment mentioned above (not shown), the detachable cassette table 109′ may be arranged in the right side surface. The cassette 109′ may be detached in the case of newly installing the processing unit 103c in the feed chamber 112 or replacing the processing unit 103b, thereby enlarging the space for transferring the unit.

In the structure mentioned above, the distance W between the line B′ corresponding to the line indicating the right end of the casing 108 and the line A′ indicating the left end of the rightward adjacent apparatus comes to the distance between the right end of the feed chamber 112 and the line A′. The space having the width constituted by the distance W comes to the space which can be used for transferring the processing units 103b and 103c. In the present embodiment, since the right end of the casing 108 does not protrude from the right surface of the feed chamber 112, the processing unit can be transferred between the line D indicating the position which is the maximum width of the processing unit 103c rightward away from the side surface constructing the right end of the feed chamber 112 in which the processing unit 103c is installed, and the line B′. Accordingly, it is possible to inhibit the casing 108 and the apparatus main body from being moved for moving the unit so as to increase the amount of work and lower the efficiency.

Particularly, in the case that the magnitude in the depth direction of the chamber portions 107 of the processing units 103a to 103c is larger than the magnitude in the depth direction of the bed portion, the processing unit can be substantially moved to the coupled position of the feed chamber 112 only by moving one of the processing units in the vertical direction of the drawing or only moving in a lateral direction slightly. Accordingly, it is possible to reduce the waste of the magnitude, particularly the width of the substantial region at a time of installing the vacuum processing apparatus 100, by setting the width Wm of the working space in the outer side of the line D to the minimum, and it is possible to improve the manufacturing efficiency of the user so as to reduce the manufacturing cost.

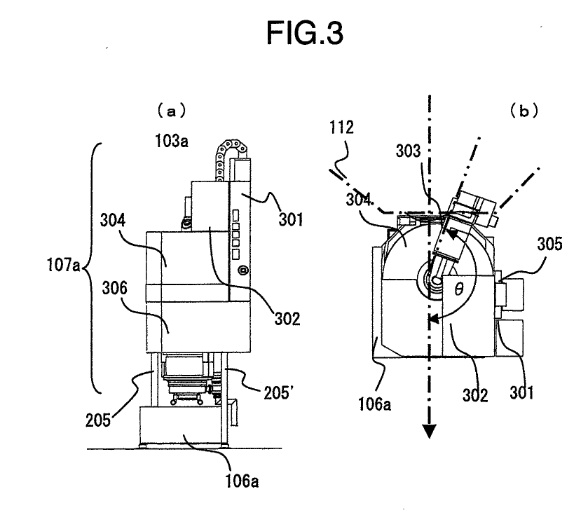

A description will be given further in detail of the structure of the processing unit 103a for the etching process shown in FIG. 1. FIGS. 3A and 3B are a front elevational view and a top elevational view as seen from a far side in the depth direction of the processing unit 103a for etching in the present embodiment shown in FIG. 1.

The processing unit 103a shown in FIG. 3A is roughly divided into upper and lower sides as mentioned above, and has a chamber portion 107a provided with a vacuum vessel 306 including a processing chamber processing the wafer in the inner portion, and a bed portion arranged on a lower floor of the chamber portion 107a and provided with a bed 106a storing a power supply or the like necessary for actuating the chamber portion 107a. Further, an exhaust apparatus 204 connected to the bottom surface of the vacuum vessel 306 is arranged in a space between the bottom surface of the vacuum vessel 306 constructing the chamber portion 107a and an upper flat surface of the bed portion, and the chamber portion 107a is retained on a box-shaped bed frame constructing the bed 106a by support members 205 and 205′.

Further, a control unit 301 for controlling a valve and a temperature within the processing chamber is arranged above the vacuum vessel 306 of the chamber portion 107. Further, in an upper portion of the chamber portion 107a, there are arranged a control unit for controlling an electric field or a magnetic field fed for exciting a plasma within the processing chamber corresponding to the inner space of the vacuum vessel 306 constructing the chamber portion, and a power supply unit 302 storing a power supply or the like for adsorbing the wafer to a top surface of the sample table arranged within the processing chamber on the basis of a static electricity.

Further, in order to generate the plasma within the processing chamber, a coil 304 generating a magnetic field fed to the processing chamber within the vacuum vessel 306 is arranged so as to surround and cover the vacuum vessel 306 or the processing chamber. Further, in order to feed the electric field into the processing chamber surrounded by the coil 304 in its upper and side peripheries, a wave guide tube 303 arranged in an upper side of the processing chamber and coupled to the upper portion of the processing chamber is arranged above the coil 304. The wave guide tube 303 is arranged in an upper side of the processing chamber in the upper portion of the chamber portion 107a in such a manner as to align its axis with a center of the sample table in the vertical direction. Further, the exhaust apparatus 204a is arranged in the lower side of the sample table in such a manner as to align an axis of a center of an opening communicating with a space in the lower side of the sample table of the processing chamber with the center of the sample table. Further, the sample table substantially has a cylindrical shape, is formed as such a shape that its axis is aligned with an axis of a center of a surface on which the wafer in the upper surface is mounted, and is arranged so as to be aligned with a center of an inner side surface of the processing chamber substantially having a cylindrical shape.

As mentioned above, the processing units 103a, 103b and 103c in accordance with the present embodiment are structured such as to be arranged by aligning the axes of the wave guide tube 303, a processing chamber 401, a discharge chamber 417, a sample table 412, a sample mounting surface in a top surface of the sample table or a wager mounted on the sample mounting surface, and the exhaust apparatus 204a with an axis corresponding to a broken line shown in FIG. 3A, and are structured such that a surface of an axis passing through the axis and being perpendicular to a surface to which the vacuum vessel 306 of the processing unit 103a and the side surface of the feed chamber 112 are coupled passes through the center of rotation of the robot within the feed chamber 112 mentioned above. The axis is shown by a broken line on FIG. 3B, and a direction of an arrow on this drawing corresponds to a depth direction (a direction in which a distance about the center of the robot is larger) of the processing units 103a radially arranged with respect to the surface coupled to the feed chamber 112. In the present embodiment, a magnitude of the processing unit 103a in this direction is set to a magnitude in the depth direction.

Further, in the processing unit 103a, the control unit 301, the power supply unit 302 and the wave guide tube 303 arranged in the upper portion of the chamber portion 107a are arranged in one side of the axis in the depth direction passing through the center axis of the processing chamber, above the right vacuum vessel 306 in the present embodiment. Further, a jack 305 for lifting up the processing units 103a to the upper side of the vacuum vessel 306 at a time of maintaining or inspecting the present processing unit 103a is connected and installed to one side of the axis in the depth direction passing through the center axis of the processing chamber, the side surface of the vacuum vessel 306 in the present embodiment. Particularly, the wave guide tube 303 is arranged such that the axis passing through the center of the tube is bent in the horizontal direction above the processing chamber, and the center axis is bent at a predetermined angle θ to the right side of the axis in the depth direction within the horizontal surface as seen from the upper side.

Further, the angle θ of the axis of the wave guide tube 303 with respect to the axis in the depth direction is made common between the processing units 103a to 103c, as shown in FIG. 2A, and the characteristic of the electric field thrown into the processing chamber within each of the units is inhibited from being uneven with respect to the peripheral direction of the sample table within the processing chamber or the wafer on the sample table. In other words, it is possible to feed the electric field having such a small difference as to be assumed to be identical in the depth direction of each of the units into the processing chamber, whereby it is possible to suppress a dispersion of a result of the process under the same condition applied to the wafer having the same specification within each of the processing units, and it is possible to improve a yield ratio and a precision of the process.

Further, since the device such as the control unit 301 or the like is arranged in one side in the depth direction, the user is prevented from being disturbed by the device at a time when the user is positioned in the other side and the depth side so as to apply the work to the processing unit 103a, and an efficiency of the maintenance work is improved. Further, the processing units 103a to 103c are coupled to the side surfaces corresponding to the adjacent respective lines of the polygonal shape so as to be adjacent, and the devices are concentrically arranged in one side, whereby it is possible to secure a wide space in which the user operates in the opposite side and the depth side. The feed chamber 112 is provided in the right side surface of the arranged chamber.

Further, the wave guide tube 303 is provided with a so-called L-shaped form in which an end portion of a portion bent in a horizontal direction is bent to an upper side. Accordingly, the wave guide tube 303 is interfered with the lid 112′ at a time of opening and closing the lid 112′ of the feed chamber 112, and it is necessary to disassemble the wave guide tube 303 in the case of maintaining and inspecting the inner portion of the feed chamber 112. Therefore, it is possible to inhibit an efficiency of the maintenance work from being significantly deteriorated, and it is possible to improve a maintenance characteristic. Accordingly, an access characteristic from the back surface and the left surface of the processing unit in the case of carrying out a periodic maintenance in any processing unit 103.

Further, as the processing unit from the top surface is shown in FIG. 3B, the bed 106a for fixing the vacuum vessel 306 and storing the devices is installed, however, the magnitude of the bed 106 is arranged approximately in an inner portion of a projected region of the chamber portion 107a including the vacuum vessel 306 onto the floor surface. In other words, the control unit 301 and the power supply unit 302 are arranged above the vacuum vessel 306 in such a manner as to be positioned within the projected surface of the vacuum vessel 306, and the bed portion including the bed 106a below the chamber portion 107a is also positioned approximately within the projected surface.

In the side surface in the depth side of the processing unit 103a of the box-shaped bed 106a, the position in the depth direction substantially coincides with the side surface corresponding to the end portion in the depth side of the vacuum vessel 306, the protrusion in the depth direction of the bed 106a is not provided, and the magnitudes in the depth direction of the both are substantially identical. On the other hand, the side surface of the bed 106a in any one of the right and left sides in the depth direction is arranged so as to protrude slightly to the corresponding side than the side surface of the vacuum vessel 306.

Particularly, the protruding side corresponds to an opposite side to the side in which the control unit 301 and the jack 305 are arranged. In the case that the user comes into the space between the side surface of this side and the other unit or the casing 108 adjacent in an outer side so as to work, the user can get on the protruding side so as to utilize as a foothold. Accordingly, a stability at a time of working can be achieved and an efficiency of the work is improved. Further, in the case that the protrusion in the depth direction is suppressed, whereby any of the processing units 103a to 103c is coupled to the side surface in the right end or left end side of the vacuum processing apparatus 100 of the feed chamber 112 and the present unit constructs one end portion in the lateral direction of the apparatus, in the present embodiment provided with the processing units 103a to 103c formed in the same layout and shape with respect to the axis in the depth direction, or the coupled surface to the feed chamber 112, it is possible to reduce the width of the region demanded for the installation in the installed floor surface.

Each of the processing units 103a to 103c is structured such that the layout of each of the portions such as the chamber portion 107 and the bed 106 provided with the vacuum vessel 306, the wave guide tube 303 and the like constructing the processing units 103a to 103c coincides or approximates such a degree as to be assumed to be substantially identical in the depth direction, in a state in which the corresponding unit is coupled to the feed chamber 112 so as to be installed to the vacuum processing apparatus 100. On the basis of the layout mentioned above, even in the case that the processing units 103a, 103b and 103c are installed at any position of the side surface of the feed chamber 112, the characteristic of the process carried out in the inner portion thereof becomes uniform, it is possible to inhibit a dispersion from being generated in the result of process in accordance with the installed position, and a yield ratio of the process is improved. Further, in order to reduce the dispersion and the unevenness of the result of the process mentioned above, a working time for finely adjusting the condition for the motion after the processing unit is attached is reduced, a non-operating time of the vacuum processing apparatus 100 is reduced, and it is possible to reduce an efficiency of the process and a cost of the product such as the semiconductor device or the like manufactured by the process.

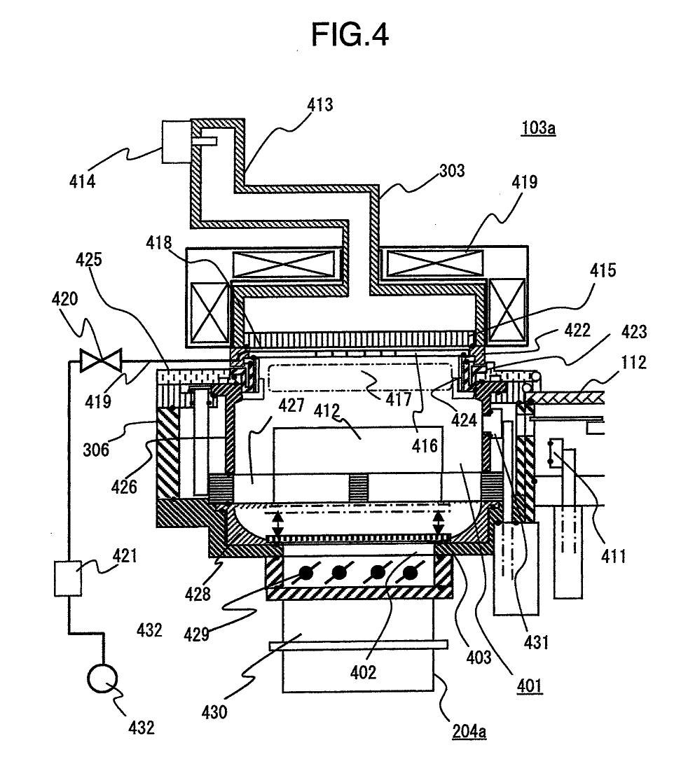

A description will be given in more detail of the structure of the processing unit in accordance with the present embodiment with reference to FIG. 4. FIG. 4 is a vertical cross sectional view schematically showing the structure of the chamber portion 107a of the processing unit 103a shown in FIG. 3.

The processing unit 103a shown in this drawing is structured such that the vacuum vessel 306 is connected to the feed chamber 112 (not shown), and the portion between the vacuum vessel 306 and the feed chamber 112 is communicated or interrupted by an opening and closing atmospheric air gate valve 411 arranged therebetween. A space in an inner portion of the feed chamber and a space in an inner side of the vacuum vessel 306 are communicated in a state in which the atmospheric air gate valve 411 is opened, and pressures of the both become approximately equal. Further, in the present embodiment, the space in the inner side of the vacuum vessel 306 corresponding to an outer chamber is provided with inner chambers 426 and 428 arranged so as to be spaced at a gap, and a processing chamber 401 and a sample table 412 are arranged in a inner side of the inner chambers 426 and 428.

If a process gate valve 431 opening and closing an opening for feeding the wafer in an airtight manner arranged in side wall portions of the atmospheric air gate valve 411 and the inner chamber 426 is opened at a time of the process, the wafer corresponding to the sample is fed onto the sample table 412 arranged in a center portion within the processing chamber 401 having a cylindrical shape in the inner portion of the vacuum vessel from the inner portion of the feed chamber 112 by the robot within the feed chamber 112 so as to be mounted. If the process is finished, the atmospheric air gate valve 411 and the process gate valve 431 are again opened, and the wafer is carried out into the feed chamber 112 via the opening of the inner chamber 426 and the opening of the vacuum vessel 306.

The wave guide tube 303 is coupled and arranged above the vacuum vessel 306 above a disc-like shower plate 416 arranged above the processing chamber 401 and constituting a ceiling member and a quartz plate 415 corresponding to a disc-like dielectric member above the shower plate. A magnetron 414 for exciting a plasma is installed in a leading end of the other end portion thereof so as to generate and feed a micro wave within the wave guide tube 303.

The generated micro wave is propagated in the inner portion of the wave guide tube 303 bent as an angle bracket shape in a cross section of the drawing, and passes through the quartz plate 415 and the shower plate 416 in which a plurality of gas introducing holes are formed below the quartz plate 415 so as to be fed into the processing chamber 401. In the wave guide tube 303, as shown in the drawing, a portion in which the magnetron 414 is arranged has an end portion 413 structured such that a tube having a rectangular cross sectional shape has an axis in a vertical direction such that a direction of propagation is up and down, and the end portion is coupled to the portion of the wave guide tube 303 set to a horizontal direction. Further, the wave guide tube 303 is again bent in the vertical direction above the processing chamber 401 and the quartz plate 415. The micro wave is propagated in a horizontal direction and further in a vertical direction after being propagated within the end portion 413 in the vertical direction, is thereafter introduced to a resonance space above the quartz plate 415 and is thereafter introduced to the downward processing chamber 401.

The end portion 413 is positioned in an upstream side of an auto tuner (not shown) arranged on the wave guide tube 303, and the magnetron 414 of the electric wave source is arranged in an upstream side of the wave guiding direction of the electric wave.

The space formed above the sample table 412 below the shower plate 416 forms a discharge chamber 417 in which the plasma is formed by an interaction generated by an electric wave on the basis of the micro wave introduced to the process gas fed from the holes of the shower plate 416 through the quartz plate 415 and a magnetic field fed from the solenoid coil 404 corresponding to a magnetic field generating portion. Further, a space is formed between the quartz plate 415 and the shower plate 416 so as to be spaced at a small gap, the process gas to be fed to the discharge chamber 417 is first fed to the space, this space is communicated with the discharge chamber 417 through the shower plate 416, and the process gas flows into the discharge chamber 417 through the holes. The space mentioned above forms a buffer chamber 418 provided in such a manner that the process gas is dispersed from a plurality of holes so as to flow into the discharge chamber 417. The process gas is fed via a process gas line 419 and a process gas interrupting valve 420 from a gas source 432 in a state in which a flow rate and a speed of the gas to be fed to the processing chamber are controlled by a controller 421.

An inner chamber 428 constructing an inner wall in a lower portion of the processing chamber 401 surrounds the space of the processing chamber 401 below the sample table 412, an opening 402 opened and closed by an elevating circular valve 403 is arranged in a bottom portion of the space, a gas and a particle within the processing chamber 401 is sucked through the opening 402 by the downward exhaust apparatus 204a, and the space within the processing chamber 401 in the upper side, the side and the lower side of the sample table 412 is depressurized. An amount and a speed of the exhaust gas are adjusted by changing a cross sectional area of a passage arranged below the opening 402 and communicating between the opening 402 and an inlet of the turbo molecular pump 430 by changing an angle of an impeller blade of each of a plurality of rotary valves 429 on the basis of a rotation of the rotary valves. The gas and the particle within the processing chamber 401 are exhausted by motions of the turbo molecular pump 430 constructing the exhaust apparatus 204a arranged below the vacuum vessel 306 and a plurality of rotary valves 429 arranged above the turbo molecular pump 430 as well as an introduction of the process gas into the processing chamber 401, and the processing chamber 401 is adjusted to a desired pressure which is suitable for the process, on the basis of a balance between the gas feed and the gas exhaust.

As mentioned above, the process gas is dispersed from a plurality of holes so as to be introduced to the discharge chamber 417, and the holes are arranged mainly at a position opposing to a position where the sample is mounted on the sample table 412, whereby an evenness of a density of the plasma is achieved as well as a function of the buffer chamber 418 capable of dispersing the gas more evenly. A lower ring 422 is arranged in an outer peripheral side of the quartz plate 415 and the shower plate 416, and an inner portion of the lower ring 422 is provided with a gas passage communicating with a gas line 419 flowing the process gas to the buffer chamber 418.

Further, in the lower side of the shower plate 416, there are arranged discharge chamber outer wall member 423 and inner wall member (quartz) 424 arranged so as to come into contact with the lower ring 422 and the shower plate 416 in lower surface thereof and forming the discharge chamber 417 in the inner side of the vacuum vessel so as to face to the plasma. In this case, in the present embodiment, the inner wall member 424 and the outer wall member 423 are structured such as to each have an approximately cylindrical shape and be approximately concentric. A heater is arranged on an outer peripheral surface of the outer wall member 423 by being wound, and adjusts a temperature of the outer wall member 423, thereby adjusting a temperature of a surface of the inner wall member 424 coming into contact with the outer wall member 423.

A discharge chamber base plate 425 coming into contact with a lower surface of the outer wall member 423 is arranged in an outer peripheral side of the outer wall member 423. The discharge chamber base plate 425 is connected to a vacuum chamber portion arranged below the discharge chamber base plate 425 in a lower surface thereof. In this case, the inner wall member 424 is a member serving as a ground electrode with respect to the sample table 412 serving as a plasma and an electrode in the inner portion of the discharge chamber 417, and has a necessary area for stabilizing an electric potential of the plasma. In order to serve as the ground electrode, it is necessary to sufficiently secure a conductivity as well as a heat conduction with respect to the lid member including the outer wall member 423 or the lower ring 422 connected in a contact manner.

The present embodiment adjusts the interaction between the surface of the wall constructing the vacuum chamber and the particle, the gas and the reactive living being contained in the plasma by adjusting the temperature of the surface of the wall constructing the vacuum chamber. Further, the temperature is kept at a higher temperature than the temperature of the sample table. As mentioned above, it is possible to set the characteristic of the plasma such as a density, a composition and the like of the plasma to a desired state, by suitably adjusting the interaction between the plasma and the wall surface of the vacuum chamber facing to the plasma.

If the wafer is mounted on the dielectric film in the upper surface of the sample table 412, the process gate valve 431 closes the opening of the inner chamber 426 so as to seal inner and outer sides of the processing chamber 401 in the inner side thereof in an airtight manner, and the wafer is adsorbed so as to be retained on the sample table 412 by feeding a direct current to the film of an electrode for electrostatic adsorption (not shown) within the dielectric film. In the present embodiment, a seal means such as an O-ring or the like is provided between the ring-shaped member coupled to the discharge chamber outer wall member 423 constructing the processing chamber 401 and an end portion of a plurality of support beams 427 connected to the outer peripheries of the upper inner chamber 426 and the sample table 412 so as to support, and the lower inner chamber 428, and the inner and outer sides are sealed in an airtight manner. Accordingly, the discharge chamber inner wall member 424 and the inner sides of the inner chambers 426 and 428 are comparted from the outer portion, and the processing chamber 401 in which the plasma is generated and the process is executed is constructed.

In accordance with the embodiment mentioned above, it is possible to suppress the waste of the space demanded for the maintenance so as to reduce the magnitude of the region demanded for substantially installing the position in which the vacuum processing apparatus 100 is installed, it is possible to enlarge the number of the apparatuses which can be installed at one position, and it is possible to improve an efficiency of the process and the manufacturing of the product. Further, it is possible to reduce the work necessary for the maintenance and the replacement, it is possible to reduce the time for which the apparatus is under non-operating state, and it is possible to improve the efficiency of the process.

It should be further understood by those skilled in the art that although the foregoing description has been made on embodiments of the invention, the invention is not limited thereto and various changes and modifications may be made without departing from the spirit of the invention and the scope of the appended claims.

1. A vacuum processing apparatus comprising:
an atmospheric air feed chamber structured such that a wafer is fed in an inner portion under an atmospheric pressure;
a plurality of cassettes arranged in a front face of the atmospheric air feed chamber and structured such that a cassette in which said wafer is stored is mounted thereon;
a vacuum feed chamber arranged in a back face side of said atmospheric air feed chamber in a state of being coupled thereto, having a polygonal plane shape and structured such that said wafer is fed in a depressurized inner portion; and
a plurality of vacuum processing chambers detachably coupled to a side surface of the vacuum feed chamber, arranged in adjacent thereto and processing said wafer fed to an inner portion from said vacuum feed chamber,
wherein said plurality of vacuum processing apparatuses includes a plurality of etching processing chamber carrying out an etching process of said wafer and at least one ashing processing chamber carrying out an ashing process of said wafer, the ashing processing chamber is coupled to a side surface in one of right and left sides as seen from said front face of said vacuum feed chamber, and said atmospheric air feed chamber is arranged so as to be biased to said one side to which the ashing processing chamber is coupled.

2. A vacuum processing apparatus as claimed in claim 1, wherein said vacuum feed chamber is provided with right and left side surfaces to which said plurality of vacuum processing chambers are capable of being coupled and rear side surfaces of the side surfaces, and said plurality of vacuum processing chambers are radially arranged around said vacuum feed chamber.

3. A vacuum processing apparatus as claimed in claim 2, wherein said ashing processing chamber is arranged in one end of a plurality of radially arranged vacuum processing chambers.

4. A vacuum processing apparatus as claimed in claim 2, wherein said ashing processing chamber is coupled to said one side of said right and left side surfaces, and at least one said etching processing chamber is operational in a state of being coupled to said rear side surface.

5. A vacuum processing apparatus as claimed in claim 3, wherein said ashing processing chamber is coupled to said one side of said right and left side surfaces, and at least one said etching processing chamber is operational in a state of being coupled to said rear side surface.

6. A vacuum processing apparatus comprising:
an atmospheric air feed chamber structured such that a wafer is fed in an inner portion under an atmospheric pressure;
a plurality of cassettes arranged in a front face of the atmospheric air feed chamber and structured such that a cassette in which said wafer is stored is mounted thereon;
a vacuum feed chamber arranged in a back face side of said atmospheric air feed chamber in a state of being coupled thereto, having a polygonal plane shape and structured such that said wafer is fed in a depressurized inner portion; and
a plurality of vacuum processing chambers detachably coupled to a side surface of the vacuum feed chamber, arranged in adjacent thereto and processing said wafer fed to an inner portion from said vacuum feed chamber,
wherein each of a plurality of etching processing chambers constituting said plurality of vacuum processing apparatuses is provided with a vacuum vessel, a wave guide tube feeding an electric field to an inner portion of the vacuum vessel, an exhaust apparatus exhausting an inner portion thereof, and a sample table on which said wafer is mounted, and arranged positions of said wave guide tube, the exhaust apparatus and the sample table with respect to said side surface are equalized between the etching processing chambers in a state in which said etching processing chamber is coupled to the side surface of said vacuum feed chamber.

7. A vacuum processing apparatus as claimed in claim 6, wherein the vacuum processing apparatus is provided with a feed robot arranged within said vacuum feed chamber and feeding said wafer on the basis of a combination of a rotation around an axis in a vertical direction and a motion of an expansion to the inner portion of said vacuum processing chamber or a contraction from the inner portion, and arranged positions of said wave guide tube, the exhaust apparatus and the sample table with respect to said axis in the vertical direction are equalized between the etching processing chambers in a state in which said etching processing chamber is coupled to the side surface of said vacuum feed chamber.

8. A vacuum processing apparatus as claimed in claim 7, wherein said wave guide tube is arranged by biasing each of said etching processing chambers to any of right and left sides with respect to said axis in the vertical direction.

9. A vacuum processing apparatus as claimed in claim 8, wherein said wave guide tube is provided with a tuner arranged in the middle thereof and adjusting an electric wave being propagated in an inner portion of the wave guide tube and an oscillator arranged in an end portion thereof and oscillating said electric wave, and is provided with a portion bent to an upper side between said tuner and said oscillator.

10. A vacuum processing apparatus as claimed in claim 8, wherein each of said etching processing chambers is provided with a crane coupled to a side wall of said vacuum vessel in said side in which said wave guide tube is biased with respect to said axis in the vertical direction.

11. A vacuum processing apparatus as claimed in claim 9, wherein each of said etching processing chambers is provided with a crane coupled to a side wall of said vacuum vessel in said side in which said wave guide tube is biased with respect to said axis in the vertical direction.

12. A vacuum processing apparatus as claimed in claim 10, wherein said vacuum vessel of each of said etching processing apparatuses is provided with an approximately rectangular parallelepiped shape, and a maintenance space for a user is provided between the adjacent etching processing apparatuses.

13. A vacuum processing apparatus as claimed in claim 11, wherein said vacuum vessel of each of said etching processing apparatuses is provided with an approximately rectangular parallelepiped shape, and a maintenance space for a user is provided between the adjacent etching processing apparatuses.
